(19) United States
(12) Patent Application Publication
(10) Pub. No.: US 2025/0241167 A1
(43) Pub. Date: Jul. 24, 2025

(54) DISPLAY DEVICE

(71) Applicant: Samsung Display Co., LTD., Yongin-si (KR)

(72) Inventors: Baek Hee LEE, Yongin-si (KR); Beom Jin KIM, Yongin-si (KR)

(73) Assignee: Samsung Display Co., LTD., Yongin-si (KR)

(21) Appl. No.: 18/787,510

(22) Filed: Jul. 29, 2024

(30) Foreign Application Priority Data
Jan. 24, 2024 (KR) 10-2024-0011137

(51) Int. Cl. H10K 59/38; H10K 59/122; H10K 59/35; H10K 59/80

(52) U.S. Cl. CPC H10K 59/38; H10K 59/122; H10K 59/35; H10K 59/877

(57) ABSTRACT

A display device includes a pixel circuit layer on a substrate, light emitting elements on the pixel circuit layer and included in a first sub-pixel, a second sub-pixel, and a third sub-pixel, a light scattering layer on the light emitting elements, a light conversion pattern on the light scattering layer and comprising color conversion particles, and a color filter layer on the light conversion pattern.

### CROSS-REFERENCE TO RELATED APPLICATION(S)

This application claims priority to and benefits of Korean Patent Application No. 10-2024-0011137 under 35 U.S.C. § 119, filed on Jan. 24, 2024, in the Korean Intellectual Property Office (KIPO), the entire contents of which are incorporated herein by reference.

### BACKGROUND

### 1. Technical Field

Embodiments of the disclosure relate to a display device.

### 2. Description of Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

### SUMMARY

Embodiments of the disclosure provide a display device with improved light efficiency.

According to an embodiment of the disclosure, a display device may include a pixel circuit layer on a substrate, light emitting elements on the pixel circuit layer, wherein the light emitting elements may be included in a first sub-pixel, a second sub-pixel, and a third sub-pixel, respectively, a light scattering layer on the light emitting elements, a light conversion pattern on the light scattering layer, the light conversion pattern including color conversion particles, and a color filter layer on the light conversion pattern.

In an embodiment, the light emitting elements may emit light of a blue color.

In an embodiment, the light scattering layer may include light scattering particles which scatter the light of the blue color.

In an embodiment, the light scattering particles may have a size in a range of about 100 nm to about 400 nm.

In an embodiment, the color conversion particles may include at least one of a quantum dot having a core-shell structure, a quantum rod having a core-shell structure, and a tetrapod quantum dot having a core-shell structure.

In an embodiment, the color conversion particles may include a nanophosphor.

In an embodiment, the light conversion pattern may include a first light conversion pattern, a second light conversion pattern, and a third light conversion pattern, each including first color conversion particles for converting the light of the blue color into light of a red color and second color conversion particles for converting the light of the blue color into light of a green color.

In an embodiment, the color filter layer may include a first color filter overlapping the first light conversion pattern in a plan view, the first color filter transmitting the light of the red color, a second color filter overlapping the second light conversion pattern in a plan view, the second color filter transmitting the light of the green color, and a third color filter overlapping the third light conversion pattern in a plan view, the third color filter transmitting the light of the blue color.

In an embodiment, the color filter layer may include a first color filter overlapping the first light conversion pattern in a plan view, the first color filter transmitting light of a yellow color, a second color filter overlapping the second light conversion pattern in a plan view, the second color filter transmitting the light of the yellow color, and a third color filter overlapping the third light conversion pattern in a plan view, the third color filter transmitting the light of the blue color.

In an embodiment, the light conversion pattern may include a first light conversion pattern including first color conversion particles for converting the light of the blue color into light of a red color, a second light conversion pattern including second color conversion particles for converting the light of the blue color into light of a green color, and a third light conversion pattern including the light scattering particles.

In an embodiment, the color filter layer may include a first color filter overlapping the first light conversion pattern in a plan view, the first color filter transmitting the light of the red color, a second color filter overlapping the second light conversion pattern in a plan view, the second color filter transmitting the light of the green color, and a third color filter overlapping the third light conversion pattern in a plan view, the third color filter transmitting the light of the blue color.

In an embodiment, each of the light emitting elements may include a first semiconductor layer including an n-type dopant, an active layer disposed on the first semiconductor layer, and a second semiconductor layer disposed on the active layer, the second semiconductor layer including a p-type dopant.

In an embodiment, each of the light emitting elements may include an anode, a light emitting structure including at least one organic light emitting layer, the light emitting structure overlapping the anode in a plan view, and a cathode provided on the light emitting structure, the cathode overlapping the anode in a plan view.

In an embodiment, the display device may further include a low refractive layer provided on the light conversion pattern.

In an embodiment, the display device may further include a bank partitioning the light scattering layer, the light conversion pattern, and the low refractive layer.

In an embodiment, a surface of the bank may have an uneven structure.

In an embodiment, the display device may further include a reflective layer provided on a top surface and a side surface of the bank.

In an embodiment, the light scattering layer may have a fine pattern.

In an embodiment, the display device may further include a capping layer disposed between the light scattering layer and the light conversion pattern.

In an embodiment, the light scattering layer may have a lattice structure including air gaps.

### BRIEF DESCRIPTION OF THE DRAWINGS

The above and other features of the disclosure will become more apparent by describing in detail embodiments thereof with reference to the accompanying drawings.

FIG. 1 is a block diagram schematically illustrating a display device in accordance with an embodiment of the disclosure.

FIG. 2 is a block diagram illustrating an embodiment of one of sub-pixels shown in FIG. 1.

FIG. 3 is a plan view illustrating an embodiment of a display panel shown in FIG. 1.

FIG. 4 is a schematic cross-sectional view illustrating an embodiment of the display panel shown in FIG. 3.

FIG. 5 is a plan view illustrating an embodiment of one of pixels shown in FIG. 3.

FIG. 6 is a schematic cross-sectional view of a pixel taken along line X-X′ shown in FIG. 5 in accordance with an embodiment of the disclosure.

FIG. 7 is a schematic cross-sectional view of a pixel taken along the line X-X′ shown in FIG. 5 in accordance with an embodiment of the disclosure.

FIG. 8 is a schematic cross-sectional view of a pixel taken along the line X-X′ shown in FIG. 5 in accordance with an embodiment of the disclosure.

FIG. 9 is a schematic cross-sectional view of a light emitting structure included in one of first to third light emitting elements shown in FIG. 8 in accordance with an embodiment of the disclosure.

FIG. 10 is a schematic cross-sectional view of a pixel taken along the line X-X′ shown in FIG. 5 in accordance with an embodiment of the disclosure.

FIG. 11 is a schematic cross-sectional view of a pixel taken along the line X-X′ shown in FIG. 5 in accordance with an embodiment of the disclosure.

FIG. 12 is a schematic cross-sectional view of a pixel taken along the line X-X′ shown in FIG. 5 in accordance with an embodiment of the disclosure.

FIG. 13 is a schematic cross-sectional view of a pixel taken along the line X-X′ shown in FIG. 5 in accordance with an embodiment of the disclosure.

FIG. 14 is a schematic block diagram illustrating an embodiment of a display system.

FIGS. 15 to 18 are perspective views illustrating application of the display system shown in FIG. 14 in accordance with an embodiment of the disclosure.

### DETAILED DESCRIPTION OF THE EMBODIMENTS

Hereinafter, embodiments of the disclosure will be described in more detail with reference to the accompanying drawings. In the description below, only a part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The technical terms used herein are used only for the purpose of illustrating a specific embodiment and not intended to limit the embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ). In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanied drawings.

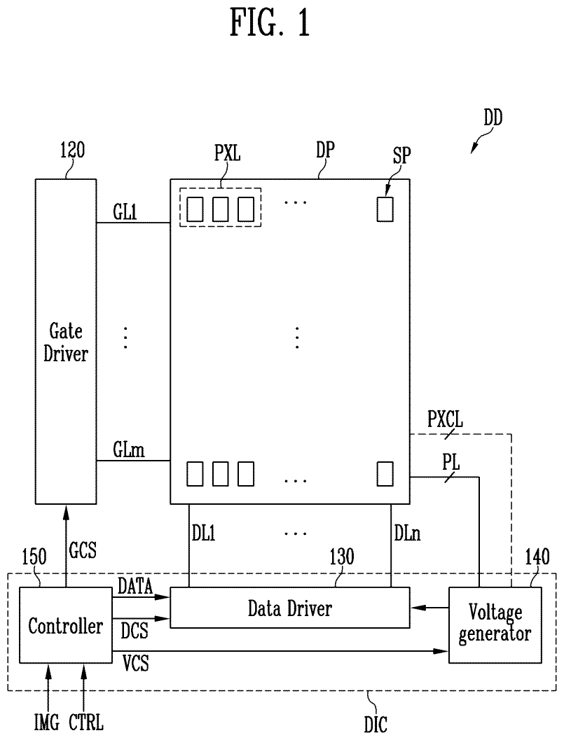

FIG. 1 is a block diagram schematically illustrating a display device in accordance with an embodiment of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

The sub-pixels SP may generate lights of two or more colors. For example, each of the sub-pixels SP may generate lights of red, green, blue, cyan, magenta, yellow, white, or the like.

Two or more sub-pixels among the sub-pixels SP may constitute a pixel PXL. For example, a pixel PXL may include three sub-pixels as shown in FIG. 1. As such, the pixel PXL may emit lights of various colors with various luminances according to a combination of lights emitted from the sub-pixels included in the pixel PXL.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal, and the like.

The gate driver 120 may be disposed at a side of the display panel DP. However, embodiments are not limited thereto. For example, the gate driver 120 may be divided into two or more drivers which are physically and/or logically divided, and the drivers may be disposed at a side of the display panel DP and another side of the display panel DP, which is opposite to the one side. As such, in some embodiments, the gate driver 120 may be disposed in various forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLm. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate multiple voltages and provide the generated voltages to components of the display device DD. The voltage generator 140 may generate multiple voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

In an embodiment, the voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a corresponding control signal CTRL. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

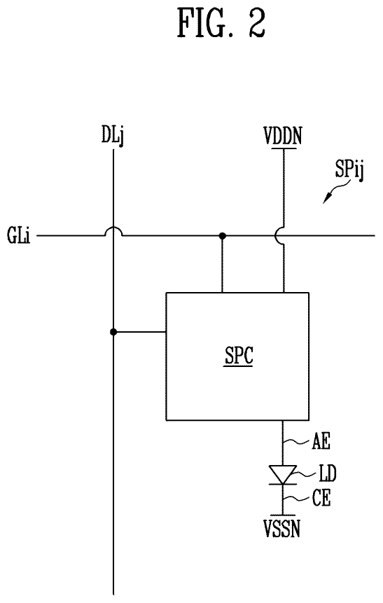

FIG. 2 is a block diagram illustrating an embodiment of one of the sub-pixels shown in FIG. 1. In FIG. 2, a sub-pixel SPij arranged on an ith row (i is an integer which is greater than or equal to 1 and is smaller than or equal to m) and a jth column (j is an integer which is greater than or equal to 1 and is smaller than or equal to n) among the sub-pixels SP shown in FIG. 1 is schematically illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

The light emitting element LD may be connected between an anode AE and a cathode CE. The anode AE may be connected to the first power voltage node VDDN through the sub-pixel circuit SPC. For example, the anode AE may be connected to the first power voltage node VDDN through one or more transistors included in the sub-pixel circuit SPC. The cathode CE may be connected to the second power voltage node VSSN. The light emitting element LD may be configured to emit light according to a current flowing from the anode AE to the cathode CE.

The sub-pixel circuit SPC may be connected to an ith gate line GLi among the first to mth gate lines GL1 to GLm shown in FIG. 1 and a jth data line DLj among the first to nth data lines DL1 to DLn shown in FIG. 1. In response to a gate signal received through the ith gate line GLi, the sub-pixel circuit SPC may control the light emitting element LD to emit light according to a data signal received through the jth data line DLj. In embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The sub-pixel circuit SPC may include a complementary Metal Oxide Silicon (CMOS) circuit. For example, the transistors of the sub-pixel circuit SPC may include P-type transistors and N-type transistors. In embodiments, the transistors of the sub-pixel circuit SPC may include a Metal Oxide Silicon Field Effect Transistor (MOSFET). In embodiments, the transistors of the sub-pixel circuit SPC may include at least one of an amorphous silicon semiconductor, a monocrystalline silicon semiconductor, polycrystalline silicon semiconductor, an oxide semiconductor, and the like.

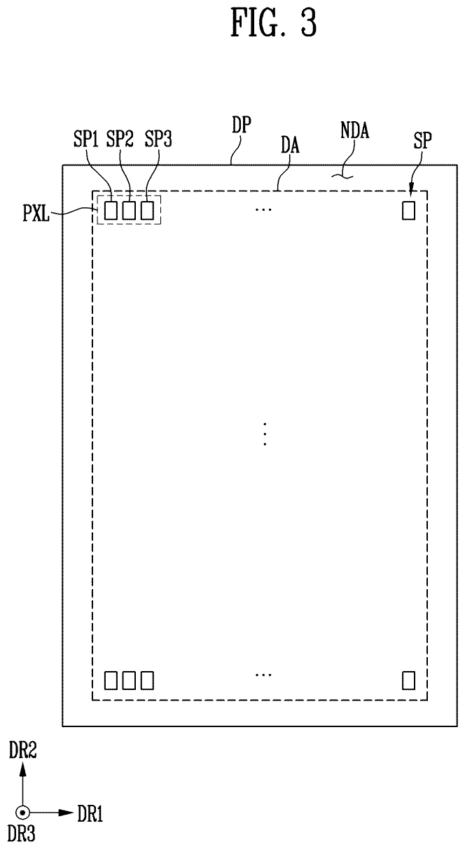

FIG. 3 is a plan view illustrating an embodiment of the display panel shown in FIG. 1.

Referring to FIG. 3, a display panel DP may include a display area DA and a non-display area NDA. The display panel DP may display an image through the display area DA. The non-display area NDA may be disposed at a periphery of the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another embodiment, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more sub-pixels among the sub-pixels SP may constitute one pixel PXL. In FIG. 3, it is illustrated that the pixel PXL includes three sub-pixels SP1 to SP3. However, embodiments are not limited thereto. For example, the pixel PXL may include two sub-pixels. Hereinafter, for convenience of description, an embodiment that the pixel PXL includes first to third sub-pixels SP1 to SP3 is described.

Each of the first to third sub-pixels SP1 to SP3 may generate light of one of various colors such as red, green, blue, cyan, magenta, and yellow. Hereinafter, for clear and simple description, an embodiment that the first sub-pixel SP1 is configured to generate light of a red color, the second sub-pixel SP2 is configured to generate light of a green color, and the third sub-pixel SP3 is configured to generate light of a blue color is described.

Each of the first to third sub-pixels SP1 to SP3 may include at least one light emitting element configured to generate light. In embodiments, light emitting elements of the first to third sub-pixels SP1 to SP3 may generate light of a same color. For example, the light emitting elements of the first to third sub-pixels SP1 to SP3 may generate light of a blue color.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, e.g., the first to mth gate lines GL1 to GLm, the first to nth data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The data driver 150, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into an integrated circuit distinguished from the display panel DP.

The display area DA may have various shapes in a plan view. The display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. A substrate of the display panel DP may include a material having flexibility.

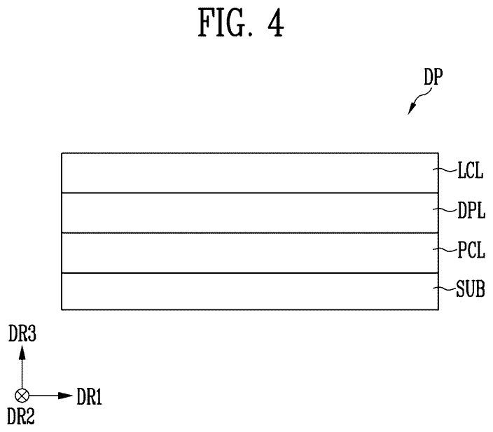

FIG. 4 is a schematic cross-sectional view illustrating an embodiment of the display panel shown in FIG. 3.

Referring to FIG. 4, a display panel DP may include a substrate SUB, and a pixel circuit layer PCL, a display panel layer DPL, and a light conversion layer LCL, which are sequentially stacked in a third direction DR3 intersecting the first and second directions DR1 and DR2 on the substrate SUB.

The substrate SUB may be made of an insulative material such as glass or resin. For example, the substrate SUB may include a glass substrate. In another embodiment, the substrate SUB may include polyimide (PI) substrate. In still another embodiment, the substrate SUB may include a silicon wafer substrate formed using a semiconductor process.

In embodiments, the substrate SUB may be made of a material having flexibility to be curvable or foldable, and have a single-layer structure or a multi-layer structure. For example, a material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

The circuit elements of the pixel circuit layer PCL may form a sub-pixel circuit SPC (see FIG. 2) of each of the sub-pixels SP shown in FIG. 3. In other words, the circuit elements of the pixel circuit layer PCL may be provided as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines for driving the display panel layer DPL.

The display panel layer DPL may be disposed on the pixel circuit layer PCL. The display panel layer DPL may include light emitting elements of the sub-pixels SP.

The light conversion layer LCL may be disposed on the display panel layer DPL. The light conversion layer LCL may include light conversion patterns having color conversion particles and/or light scattering particles. For example, color conversion particles may include quantum dots. The quantum dots may change a wavelength (or color) of light emitted from the display panel layer DPL. In embodiments, the light conversion patterns may be omitted.

The light conversion layer LCL may further include a color filter layer including color filters. The color filter may selectively transmit light having a specific wavelength (or specific color). In embodiments, the color filter layer may be omitted.

A window for protecting an exposed surface (or top surface) of the display panel DP may be provided on the light conversion layer LCL. The window may protect the display panel DP from external impact. The window may be bonded to the light conversion layer LCL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

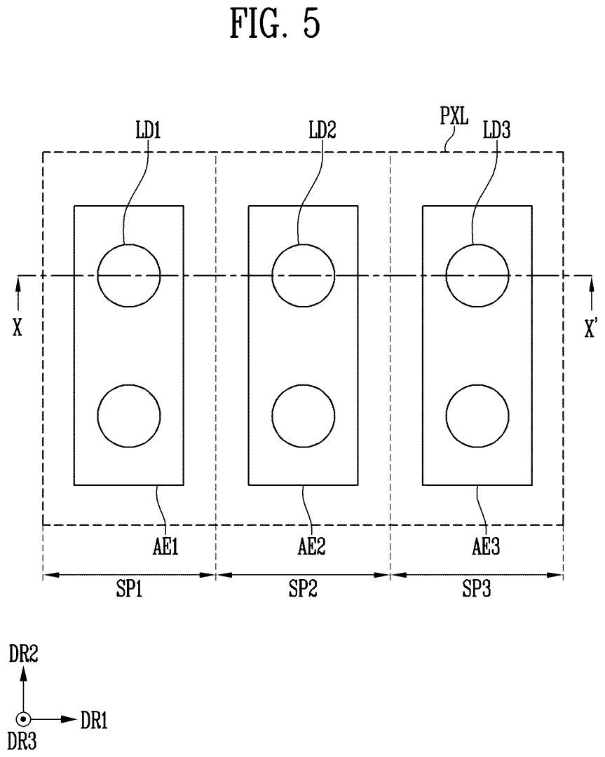

FIG. 5 is a plan view illustrating an embodiment of one of the pixels shown in FIG. 3.

Referring to FIG. 5, a pixel PXL may include first to third sub-pixels SP1 to SP3. The first to third sub-pixels SP1 to SP3 may be arranged in the first direction DR1. However, the arrangement of the pixel PXL is not limited thereto, and the pixel PXL may be variously changed in some embodiments. For example, the first to third sub-pixels SP1 to SP3 may be arranged in zigzag.

First to third anodes AE1 to AE3 may be disposed in the first to third sub-pixels SP1 to SP3, respectively. The first anode AE1 may be provided as an anode AE (see FIG. 2) connected to a sub-pixel circuit SPC (see FIG. 2) of the first sub-pixel SP1. The second anode AE2 may be provided as an anode AE connected to a sub-pixel circuit SPC of the second sub-pixel SP2.

The third anode AE3 may be provided as an anode AE connected to a sub-pixel circuit SPC of the third sub-pixel SP3.

One or more first light emitting elements LD1, one or more second light emitting elements LD2, and one or more third light emitting elements LD3 may be disposed on the first to third anodes AE1 to AE3, respectively. The first light emitting elements LD1 may be connected to the first anode AEL. The second light emitting elements LD2 may be connected to the second anode AE2. The third light emitting elements LD3 may be connected to the third anode AE3. In case that multiple light emitting elements are provided in each sub-pixel, each anode may have a shape extending in a direction such as the second direction DR2, and light emitting elements connected the anode may be arranged in a same direction.

The first light emitting elements LD1 may be provided as the light emitting element LD shown in FIG. 2, which is included in the first sub-pixel SP1. The second light emitting elements LD2 may be provided as the light emitting element LD shown in FIG. 2, which is included in the second sub-pixel SP2. The third light emitting elements LD3 may be provided as the light emitting element LD shown in FIG. 2, which is included in the third sub-pixel SP3. In case that multiple light emitting elements are provided in one sub-pixel, the light emitting elements may be connected in parallel between an anode and a cathode to be provided as the light emitting element LD shown in FIG. 2.

The first light emitting elements LD1, the second light emitting elements LD2, and the third light emitting elements LD3 may be inorganic light emitting diodes including an inorganic light emitting material. However, embodiments are not limited thereto. For example, the first light emitting elements LD1, the second light emitting elements LD2, and the third light emitting elements LD3 may be organic light emitting diodes.

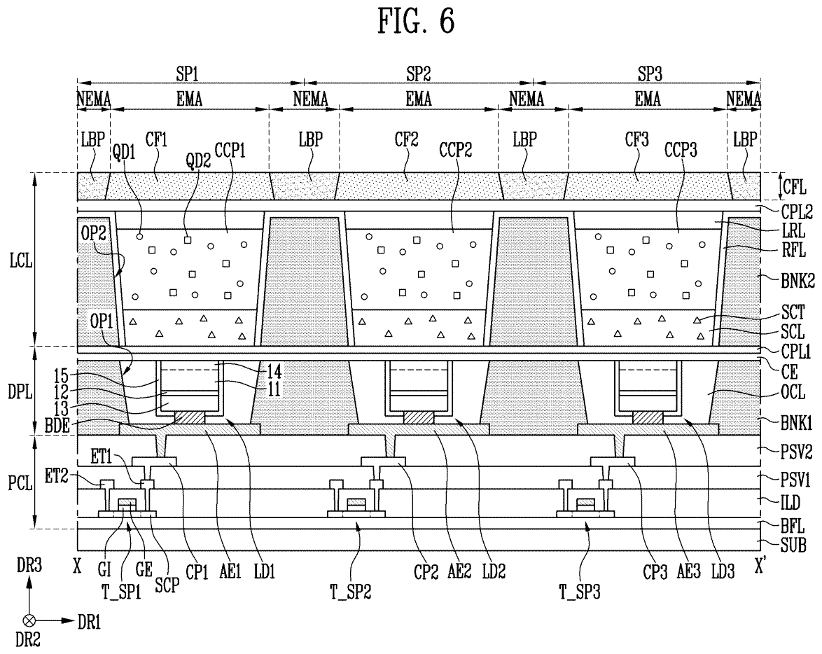

FIG. 6 is a schematic cross-sectional view of a pixel taken along line X-X′ shown in FIG. 5 in accordance with an embodiment of the disclosure.

Referring to FIGS. 5 and 6, a pixel circuit layer PCL, a display panel layer DPL, and a light conversion layer LCL may be sequentially disposed on a substrate SUB.

The pixel circuit layer PCL may include insulating layers, semiconductor patterns, and conductive patterns, which are stacked on the substrate SUB. The insulating layers may include a buffer layer BFL, one or more interlayer insulating layers ILD, and one or more passivation layers PSV1 and PSV2. The semiconductor patterns and the conductive patterns may be located between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1 to SP3 may include transistors and one or more capacitors. The semiconductor patterns and the conductive patterns of the pixel circuit layer PCL may form the transistors and the capacitors of the sub-pixel circuit SPC. The conductive patterns of the pixel circuit layer PCL may further form lines, e.g., the first to mth gate lines GL1 to GLm, the first to nth data lines DL1 to DLn, the power lines PL, and the pixel control lines PXCL, which are shown in FIG. 1.

The buffer layer BFL may be disposed on a surface of the substrate SUB. The buffer layer BFL may prevent an impurity from being diffused into circuit elements and lines, which are included in the pixel circuit layer PCL. The buffer layer BFL may include an inorganic insulating layer including an inorganic material. In embodiments, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer or a multi-layer. In case that the buffer layer BFL is provided as a multi-layer, layers of the multi-layer may be formed of a same material or be formed of different materials.

In embodiments, one or more barrier layers may be disposed between the substrate SUB and the buffer layer BFL. Each of the barrier layers may include polyimide.

First to third transistors T_SP1 to T_SP3 respectively corresponding to the first to third sub-pixels SP1 to SP3 may be disposed on the buffer layer BFL. The first transistor T_SP1 may be one of the transistors of the sub-pixel circuit SPC included in the first sub-pixel SP1. The second transistor T_SP2 may be one of the transistors of the sub-pixel circuit SPC included in the second sub-pixel SP2. The third transistor T_SP3 may be one of the transistors of the sub-pixel circuit SPC included in the third sub-pixel SP3. Each of the first to third transistors T_SP1 to T_SP3 may be a transistor connected to an anode among transistors of a corresponding sub-pixel.

The first transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be another one of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the first transistor T_SP1 in a plan view (in the third direction DR3). The channel region may be a semiconductor pattern undoped with an impurity, and may be an intrinsic semiconductor. Each of the first contact region and the second contact region may be a semiconductor pattern doped with an impurity. For example, a p-type impurity may be used as the impurity, but embodiments are not limited thereto.

The semiconductor pattern SCP may include one of various types of semiconductors, e.g., one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride (SiNₓ), silicon oxide (SiOₓ), silicon oxynitride (SiOₓN_{y}), and a metal oxide such as aluminum oxide (AlOₓ). However, the interlayer insulating layers ILD are not limited thereto. For example, one of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on the semiconductor pattern SCP and the buffer layer BFL, to cover the semiconductor pattern SCP and the buffer layer BFL. As the number of layers required in the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP in a plan view. The gate electrode GE may be provided as a single layer including at least one of copper (Cu), molybdenum (Mo), tungsten (W), aluminum neodymium (AlNd), titanium (Ti), aluminum (Al), and silver (Ag). In embodiments, the gate electrode GE may be provided as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one of copper (Cu), molybdenum (Mo), tungsten (W), aluminum neodymium (AlNd), titanium (Ti), aluminum (Al), and silver (Ag).

Although the first and second terminals ET1 and ET2 are illustrated as separate electrodes electrically connected to the semiconductor pattern SCP, embodiments are not limited thereto. In some embodiments, the first terminal ET1 may be the first contact region adjacent to a side of the channel region of the semiconductor pattern SCP, and the second terminal ET2 may be the second contact region adjacent to another side of the channel region of the semiconductor pattern SCP. The first terminal ET1 may be electrically connected to the first light emitting element LD1 through a connection means such as a bridge electrode disposed on at least one of the interlayer insulating layers ILD.

In embodiments, the first transistor T_SP1 may be configured as a low temperature poly-silicon transistor. However, embodiments are not limited thereto. For example, the first transistor T_SP1 may be configured as an oxide semiconductor transistor. In embodiments, the sub-pixel circuit of each sub-pixel may include different types of transistors. For example, the first transistor T_SP1 may be configured as a low temperature poly-silicon transistor, and another transistor of the first sub-pixel SP1 may be configured as an oxide semiconductor transistor. An oxide semiconductor of the corresponding oxide semiconductor transistor may be disposed on one of the interlayer insulating layers ILD instead of an insulating layer on which the semiconductor pattern SCP of the first transistor T_SP1.

An embodiment that the first transistor T_SP1 is a transistor having a top gate structure is described. However, embodiments are not limited thereto. For example, the first transistor T_SP1 may be a transistor having a bottom gate structure. The structure of the first transistor T_SP1 may be variously changed.

Each of the second and third transistors T_SP2 and TSP3 may be configured identically to the first transistor T_SP1. Hereinafter, overlapping descriptions will be omitted.

At least a portion of various lines of the display panel DP and/or the display device DD may be further disposed on the interlayer insulating layers ILD.

A first passivation layer PSV1 may be disposed over the first to third transistors T_SP1 to T_SP3. The passivation layer may be a protective layer or a via layer. The first passivation layer PSV1 may protect components disposed under the first passivation layer PSV1, and provide a flat top surface.

First to third connection patterns CP1 to CP3 may be disposed on the first passivation layer PSV1. The first to third connection patterns CP1 to CP3 may be respectively connected to first terminals ET1 of the first to third transistors T_SP1 to T_SP3 while penetrating the first passivation layer PSV1. The first to third connection patterns CP1 to CP3 may include at least one of copper (Cu), molybdenum (Mo), tungsten (W), aluminum neodymium (AlNd), titanium (Ti), aluminum (Al), and silver (Ag).

At least a portion of various lines of the display panel DP and/or the display device DD may be further disposed on the first passivation layer PSV1.

A second passivation layer PSV2 may be disposed on the first to third connection patterns CP1 to CP3 and the first passivation layer PSV1. The second passivation layer PSV2 may protect components disposed under the second passivation layer PSV2, and provide a flat top surface.

Each of the first and second passivation layers PSV1 and PSV2 may include an inorganic insulating layer including an inorganic material and/or an organic insulating layer including an organic material. The inorganic insulating layer may include, for example, at least one of silicon oxide (SiOₓ), silicon nitride (SiNₓ), silicon oxynitride (SiOₓN_{y}), and a metal oxide such as aluminum oxide (AlOₓ). The organic insulating layer may include, for example, at least one of an acrylic resin, an epoxy resin, a phenolic resin, a polyamide resin, a polyimide resin, an unsaturated polyester resin, a poly-phenylene ether resin, a poly-phenylene sulfide resin, and a benzocyclobutene resin.

The first and second passivation layers PSV1 and PSV2 and one of the interlayer insulating layers ILD may include a same material, but embodiments are not limited thereto. Each of the first and second passivation layers PSV1 and PSV2 may be provided as a single layer, or a multi-layer.

The display panel layer DPL may be disposed on the second passivation layer PSV2. The display panel layer DPL may include first to third anodes AE1 to AE3, a first bank BNK1, first to third light emitting elements LD1 to LD3, an overcoat layer OCL, a cathode CE, and a first capping layer CPL1. The first to third light emitting elements LD1 to LD3 shown in FIG. 6 may be configured with a light emitting diode of micro scale or nano scale.

On the pixel circuit layer PCL, the first to third anodes AE1 to AE3 may be disposed in the first to third sub-pixels SP1 to SP3, respectively.

The first anode AE1 may be electrically connected to the first connection electrode CP1 through a contact hole penetrating the second passivation layer PSV2. The second anode AE2 may be electrically connected to the second connection electrode CP2 through another contact hole penetrating the second passivation layer PSV2. The third anode AE3 may be electrically connected to the third connection electrode CP3 through still another contact hole penetrating the second passivation layer PSV2. As such, the first to third anodes AE1 to AE3 may be electrically connected to the first to third transistors T_SP1 to T_SP3, respectively.

The first bank BNK1 may be disposed on the first to third anodes AE1 to AE3. The first bank BNK1 may include first openings OP1 exposing portions of the first to third anodes AE1 to AE3 in a plan view. The first to third light emitting elements LD1 to LD3 may be disposed in the first openings OP1 of the first bank BNK1. As such, the first bank BNK1 may be provided as a pixel defining layer defining areas in which the first to third light emitting elements LD1 to LD3 are located.

The first bank BNK1 may include a light blocking material, to prevent light mixture between adjacent sub-pixels. In embodiments, the first bank BNK1 may include an organic material. For example, the first bank BNK1 may include an organic insulating material such as an acrylic resin, an epoxy resin, a phenolic resin, a polyamide resin, or a polyimide resin. In order to further improve light emission efficiency, a reflective layer including a reflective material may be further disposed on side surfaces of the first bank BNK1, which are adjacent to the first openings OP1.

The first to third light emitting elements LD1 to LD3 may be disposed on the first to third anodes AE1 to AE3, respectively. The first to third light emitting elements LD1 to LD3 may be bonded to the first to third anodes AE1 to AE3, respectively.

The first light emitting element LD1 may include a bonding electrode BDE, a first semiconductor layer 11, an active layer 12, a second semiconductor layer 13, and an auxiliary layer 14. The first light emitting element LD1 may be implemented as a vertical light emitting stack structure in which the bonding electrode BDE, the second semiconductor layer 13, the active layer 12, the first semiconductor layer 11, and the auxiliary layer 14 are sequentially stacked in the third direction DR3. However, embodiments are not limited thereto. For example, the first light emitting element LD1 may be implemented as a flip chip type light emitting element or a lateral chip type light emitting element.

The first semiconductor layer 11 may provide electrons to the active layer 12. The first semiconductor layer 11 may include at least one n-type semiconductor layer. For example, the first semiconductor layer 11 may include at least one of gallium nitride (GaN), aluminum gallium nitride (AlGaN), indium gallium nitride (InGaN), aluminum nitride (AlN), and indium nitride (InN), and be an n-type semiconductor layer doped with a first conductive dopant (or n-type dopant) such as silicon (Si), germanium (Ge) or tin (Sn). However, the material constituting the first semiconductor layer 11 is not limited thereto, and various materials may constitute the first semiconductor layer 11. In an embodiment, the first semiconductor layer 11 may include a gallium nitride (GaN) semiconductor material doped with a first conductive dopant (or n-type dopant). In some embodiments, the first semiconductor layer 11 along with the auxiliary layer 14 may constitute an n-type semiconductor layer.

The active layer 12 may be disposed on the first semiconductor layer 11, and be an area in which electrons and holes are recombined. As electrons and holes may be recombined in the active layer 12, light may be generated, which has a level changed to a low energy level and has a wavelength corresponding to the low energy level. The active layer 12 may be formed in a single quantum well structure or a multi-quantum well structure. In case that the active layer 12 is formed in the multi-quantum well structure, a unit including a barrier layer, a strain reinforcing layer, and a well layer may be repeatedly stacked each other, to form the active layer 12. However, embodiments of the active layer 12 are not limited thereto.

The second semiconductor layer 13 may be disposed on the active layer 12, and provide holes to the active layer 12. The second semiconductor layer 13 may include a semiconductor layer of which type is different from the type of the first semiconductor layer 11. In an embodiment, the second semiconductor layer 13 may include at least one p-type semiconductor layer. For example, the second semiconductor layer 13 may include at least one of gallium nitride (GaN), aluminum gallium nitride (AlGaN), indium gallium nitride (InGaN), aluminum nitride (AlN), and indium nitride (InN), and be a p-type semiconductor layer doped with a second conductive dopant (or p-type dopant) such as magnesium (Mg), zinc (Zn), calcium (Ca), strontium (Sr) or barium (Ba). However, the material constituting the second semiconductor layer 13 is not limited thereto, and various materials may constitute the second semiconductor layer 13. For example, the second semiconductor layer 13 may include a gallium nitride (GaN) semiconductor material doped with a second conductive dopant (or p-type dopant).

The bonding electrode BDE may be electrically connected to the second semiconductor layer 13. The bonding electrode BDE may include a eutectic metal.

The auxiliary layer 14 may include a gallium nitride (GaN) semiconductor material undoped with an impurity. In some embodiments, the auxiliary layer 14 along with the first semiconductor layer 11 may constitute an n-type semiconductor layer.

The first light emitting element LD1 may further include an insulative film 15 covering an outer circumferential surface of the vertical light emitting stack structure. The insulative film 15 may prevent an electrical short circuit which may occur while the active layer 12 is in contact with another conductive material except the first and second semiconductor layers 11 and 13. The insulative film 15 may include a transparent insulating material. The insulative film 15 may be configured to expose a bottom surface of the bonding electrode BDE, which is opposite to the second semiconductor layer 13. Also, the insulative film 15 may be configured to expose a top surface of the auxiliary layer 14, which is to be in contact with the cathode CE.

The bottom surface of the bonding electrode BDE may be connected to the first anode AE1. The top surface of the auxiliary layer 14 may be connected to the cathode CE. Accordingly, the first light emitting element LD1 may be electrically connected between the first anode AE1 and the cathode CE.

In embodiments, a reflective electrode may be disposed between the bonding electrode BDE and the second semiconductor layer 13. Light emitted from the first light emitting element LD1 may be efficiently output toward the light conversion layer LCL. The reflective electrode may be configured with a conductive material having a predetermined or selectable reflectivity. The conductive material may include an opaque metal. The opaque metal may include silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, the material of the reflective electrode is not limited thereto.

Each of the second and third light emitting elements LD2 and LD3 may be configured identically to the first light emitting element LD1.

The overcoat layer OCL may be disposed in the first openings OP1 in which the first to third light emitting elements LD1 to LD3 are disposed. The overcoat layer OCL may fix the first to third light emitting elements LD1 to LD3 bonded to the first to third anodes AE1 to AE3 not to move. Also, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The cathode CE may be disposed on the first to third light emitting elements LD1 to LD3. The cathode CE may be entirely disposed on the first bank BNK1, the first to third light emitting elements LD1 to LD3, and the overcoat layer OCL. The cathode CE may be in contact with the auxiliary layer 14 of each of the first to third light emitting elements LD1 to LD3. The cathode CE may be electrically connected to the second power voltage node VSSN shown in FIG. 2. The second power voltage applied to the second power voltage node VSSN may be transferred to the first to third light emitting elements LD1 to LD3 through the cathode CE.

The cathode CE may be substantially transparent or translucent to satisfy a predetermined or selectable light transmittance. In embodiments, the cathode CE may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the cathode CE is not limited thereto.

The first capping layer CPL1 may be disposed over the cathode CE. The first capping layer CPL1 may protect components disposed under the first capping layer CPL1, such as the cathode CE and the first to third light emitting elements LD1 to LD3, from external moisture, humidity, and the like. The first capping layer CPL1 may include at least one of silicon nitride (SiNₓ), silicon oxide (SiOₓ), silicon oxynitride (SiOₓN_{y}), and a metal oxide such as aluminum oxide (AlOₓ). However, the material of the first capping layer CPL1 is not limited thereto.

The light conversion layer LCL may be disposed on the first capping layer CPL1. The light conversion layer LCL may include a second bank BNK2, a reflective layer RFL, a light scattering layer SCL, first to third light conversion patterns CCP1 to CCP3, a low refractive layer LRL, a second capping layer CPL2, and a color filter layer CFL.

The second bank BNK2 may be disposed on the first capping layer CPL1. The second bank BNK2 may overlap the first bank BNK1 in a plan view. The second bank BNK2 may have second openings OP2 overlapping the first openings OP1 in a plan view. The second bank BNK2 may partition the light scattering layer SCL, the first to third light conversion patterns CCP1 to CCP3, which correspond to the first to third sub-pixels SP1 to SP3, and the low refractive layer LRL.

The second bank BNK2 may include a light blocking material, to prevent light mixture between adjacent pixels and the first to third sub-pixels SP1 to SP3. In embodiments, the second bank BNK2 may include an organic material. For example, the second bank BNK2 may include an organic insulating material such as an acrylic resin, an epoxy resin, a phenolic resin, a polyamide resin, or a polyimide resin.

The reflective layer RFL may be disposed on side surfaces and top surfaces of the second bank BNK2, which are adjacent to the second openings OP2. The reflective layer RFL may be configured to reflect incident light, and accordingly, light emission efficiency may be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy thereof. However, embodiments are not limited thereto.

Emission areas EMA and a non-emission area NEMA of the first to third sub-pixels SP1 to SP3 may be defined by the second bank BNK2. An area which the second bank BNK2 overlaps in a plan view may correspond to the non-emission area NEMA. Areas overlapping the second openings OP2 of the second bank BNK2 may correspond to the emission areas EMA.

On the first capping layer CPL1, the light scattering layer SCL may be disposed in the second openings OP2.

In embodiments, the light scattering layer SCL may scatter incident light, thereby outputting the incident light in a Lambertian form. Light emitted while passing through the light scattering layer SCL may have a Lambertian distribution. For example, light of a blue color, which is emitted from the first to third light emitting elements LD1 to LD3 to be incident onto the light scattering layer SCL may be output in the Lambertian form via the light scattering layer SCL. The light scattering layer SCL may scatter light emitted from the first to third light emitting elements LD1 to LD of micro scale or nano scale, which are dot light sources, thereby forming a surface light source. Accordingly, diffuse reflection (or scattering) and recycling of light of the blue color may effectively occur in the first to third light conversion patterns CCP1 to CCP3, so that the light conversion efficiency of first color conversion particles QD1 and second color conversion particles QD2 may be improved. For example, the light scattering layer SCL may increase a light path of light of the blue color in a high resolution (e.g., 2000 ppi or more), thereby effectively inducing the diffuse reflection and cycling of the light of the blue color.

The light scattering layer SCL may include light scattering particles SCT. For example, the light scattering particles SCT may include at least one of silica, titanium oxide (TiO₂), zirconium oxide (ZrO₂), aluminum oxide (Al₂O₃), indium oxide (In₂O₃), zinc peroxide (ZnO₂), tin oxide (SnO₂), antimony oxide (Sb₂O₃), and indium tin oxide (ITO). The light scattering particles SCT may have a size suitable for outputting incident light in the Lambertian form. For example, the size of the light scattering particles SCT may be in a range of about 100 nm to about 400 nm.

On the light scattering layer SCL, the first to third light conversion patterns CCP1 to CCP3 may be disposed in the second openings OP2.

The first to third light conversion patterns CCP1 to CCP3 may include color conversion particles and light scattering particles. The color conversion particles may change the wavelength of incident light, thereby converting the incident light into light of another color. Also, the color conversion particles may scatter incident light. The light scattering particles may scatter incident light.

In an embodiment, the color conversion particles may include at least one of a quantum dot having a core-shell structure, a quantum rod having a core-shell structure, and a tetrapod quantum dot having a core-shell structure. The core may include at least one of CdSe, CdS, CdTe, ZnS, ZnSe, ZnTe, CdSeTe, CdZnS, CdSeS, PbSe, PbS, PbTe, AgInZnS, HgS, HgSe, HgTe, GaN, GaP, GaAs, InP, InZnP, InGaP, InGaN InAs, AgInGaS, CuInGaS, and ZnO. The shell may include at least one of CdS, CdSe, CdTe, CdO, ZnS, ZnSe, ZnTe, ZnO, InP, InS, GaP, GaN, GaO, InZnP, InGaP, InGaN, InZnSCdSe, PbS, TiO, SrSe, and HgSe.

In an embodiment, the color conversion particles may include a nano phosphor. The nano phosphor may be configured with an inorganic material. For example, the nano phosphor may include at least one of garnet, silicate, a sulfide, an oxynitride, a nitride, and an aluminate. For example, the nano phosphor may include at least one of Y₃Al₅O₁₂:Ce³⁺(YAG:Ce), Tb3Al₅O₁₂:Ce³⁺(TAG:Ce), (Sr,Ba,Ca)₂SiO₄:Eu²⁺, (Sr,Ba,Ca,Mg,Zn)₂Si(OD)₄:Eu²⁺ (D=F, Cl, S, N or Br), Ba₂MgSi₂O₇:Eu²⁺, Ba₂SiO₄:Eu²⁺, Ca₃(Sc,Mg)₂Si₃O₁₂:Ce³⁺, (Ca,Sr)S:Eu²⁺, (Sr,Ca)Ga₂S₄:Eu²⁺, SrSi₂O₂N₂:Eu²⁺, SiAlON:Ce³⁺, p-SiAlON:Eu²⁺, Ca-α-SiAlON:Eu²⁺, Ba₃Si₆Oi₂N₂:Eu²⁺, CaAlSiN₃:Eu²⁺, (Sr,Ca)AlSiN₃:Eu²⁺, Sr₂Si₅Ns:Eu²⁺, (Sr,Ba)Al₂O₄:Eu²⁺, (Mg,Sr)Al₂O₄:Eu²⁺, and BaMg₂Al₁₆O₂₇:Eu²⁺.

In embodiments, the first to third light emitting elements LD1 to LD3 may emit light of a blue color. In an embodiment, the first to third light conversion patterns CCP1 to CCP3 may be substantially configured with a same material. For example, the first light conversion pattern CCP1 may include the first color conversion particles QD1 for converting light of the blue color into light of a red color, the second color conversion particles QD2 for converting light of the blue color into light of a green color, and the light scattering particles. In an embodiment, the second light conversion pattern CCP2 may include the first color conversion particles QD1 for converting light of the blue color into light of the red color, the second color conversion particles QD2 for converting light of the blue color into light of the green color, and the light scattering particles. In an embodiment, the third light conversion pattern CCP3 may include the first color conversion particles QD1 for converting light of the blue color into light of the red color, the second color conversion particles QD2 for converting light of the blue color into light of the green color, and the light scattering particles.

Accordingly, light of a same color may be emitted from the first to third light conversion patterns CCP1 to CCP3. For example, light of a white color may be emitted from the first to third light conversion patterns CCP1 to CCP3. The light of the white color, which is emitted from the first to third light conversion patterns CCP1 to CCP3, may be emitted as light of the red color, light of the green color, and light of the blue color while passing through first to third color filters CF1 to CF3 of the color filter layer CFL. Therefore, the first to third sub-pixels SP1 to SP3 may be provided as a red sub-pixel, a green sub-pixel, and a blue sub-pixel, respectively.

On the first to third light conversion patterns CCP1 to CCP3, the low refractive layer LRL may be disposed in the second openings OP2.

In embodiments, the low refractive layer LRL may have a refractive index lower than a refractive index of each of the first to third light conversion patterns CCP1 to CCP3 and the first to third color filters CF1 to CF3. The low refractive layer LRL may be configured to refract or totally reflect light according to an incident angle of the corresponding light. The low refractive layer LRL may again provide the first to third light conversion patterns CCP1 to CCP3 with light passing through the first to third light conversion patterns CCP1. Accordingly, the light conversion efficiency of the first to third light conversion patterns CCP1 to CCP3 may be improved. The low refractive layer LRL may have a thickness in a range of about 0.5 μm to about 1 μm.

The second capping layer CPL2 may be disposed over the low refractive layer LRL. The second capping layer CPL2 may be entirely disposed on the low refractive layer LRL and the reflective layer RFL. The second capping layer CPL2 may protect components disposed under the second capping layer CPL2, such as the low refractive layer LRL and the first to third light conversion patterns CCP1 to CCP3, from external moisture, humidity, and the like. The second capping layer CPL2 may include at least one of silicon nitride (SiNₓ), silicon oxide (SiOₓ), silicon oxynitride (SiOₓN_{y}), and a metal oxide such as aluminum oxide (AlOₓ). However, the material of the second capping layer CPL2 is not limited thereto.

The color filter layer CFL may be disposed on the second capping layer CPL2. The color filter layer CFL may include the first to third color filters CF1 to CF3 and light blocking patterns LBP. The first to third color filters CF1 to CF3 may overlap the first to third light conversion patterns CCP1 to CCP3 in a plan view, respectively. Each of the first to third color filters CF1 to CF3 may selectively transmit light in a desired wavelength range.

In embodiments, the first color filter CF1 may selectively transmit light of the red color. In embodiments, the second color filter CF2 may selectively transmit light of the green color. In embodiments, the third color filter CF3 may selectively transmit light of the blue color. In embodiments, the first color filter CF1 and the second color filter CF2 may reflect light of the blue color. Accordingly, the light conversion efficiency of the first to third light conversion patterns CCP1 to CCP3 may be improved through recycling of light of the blue color. However, embodiments are not limited thereto. For example, the first color filter CF1 and the second color filter CF2 may selectively transmit light of a yellow color, and the third color filter CF3 may selectively transmit light of the blue color.

The light blocking patterns LBP may be disposed between the color filters CF1 to CF3. The emission areas (or light emission areas) EMA and the non-emission area NEMA of the first to third sub-pixels SP1 to SP3 may be defined by the light blocking patterns LBP. Areas corresponding to the light blocking patterns LBP may correspond to the non-emission area NEMA. Areas not overlapping the light blocking patterns LBP in a plan view may correspond to the emission areas EMA.

In embodiments, the light blocking patterns LBP may include at least one of various kinds of light blocking materials. In embodiments, each of the light blocking patterns LBP may be provided in the form of a multi-layer in which at least two color filters among the first to third color filters CF1 to CF3 overlap with each other in a plan view. For example, each of the light blocking patterns LBP may be formed as the first to third color filters CF1 to CF3 overlap with each other. For example, a light blocking pattern between the first and second color filters CF1 and CF2 among the light blocking patterns LBP may be formed as a multi-layer in which the first and second color filters CF1 and CF2 overlap with each other, and a light blocking pattern between the second and third color filters CF2 and CF3 among the light blocking patterns LBP may be formed as a multi-layer in which the second and third color filters CF2 and CF3 overlap with each other. For example, a light blocking pattern between the first color filter CF1 and a third color filter CF3 of an adjacent pixel may be formed as a multi-layer in which the first and third color filters CF1 and CF3 overlap with each other. As such, each of the first to third color filters CF1 to CF3 may extend to the non-emission area NEMA to form the light blocking patterns LBP.

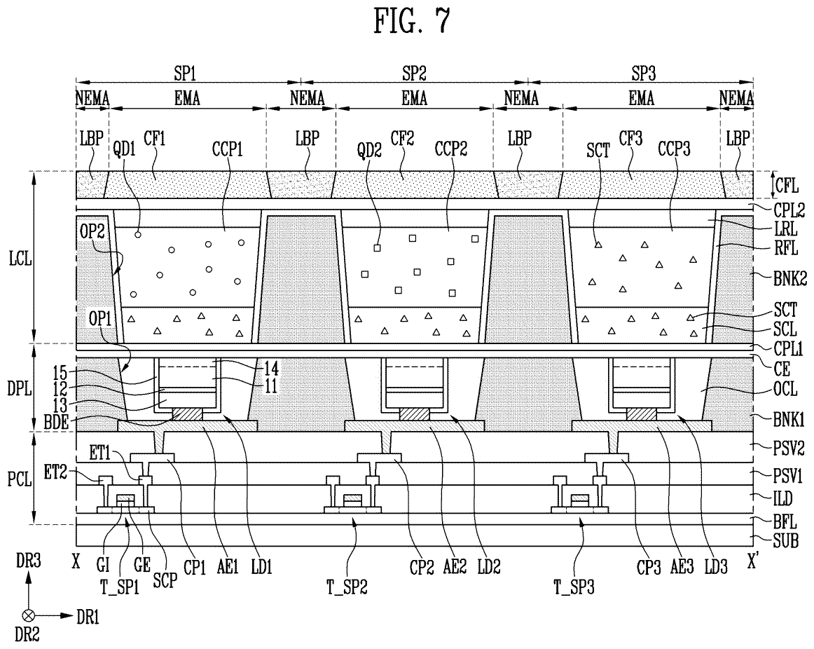

FIG. 7 is a schematic cross-sectional view of a pixel taken along the line X-X′ shown in FIG. 5 in accordance with an embodiment of the disclosure. In relation to FIG. 7, descriptions of portions overlapping with those shown in FIG. 6 will be simplified or omitted.

Referring to FIG. 7, the first to third light emitting elements LD1 to LD3 may emit light of the blue color. In an embodiment, the first to third conversion patterns CCP1 to CCP3 may be configured with different materials. For example, the first light conversion patterns CCP1 may include the first color conversion particles QD1 for converting light of the blue color into light of the red color and the light scattering particles. For example, the second light conversion pattern CCP2 may include the second color conversion particles QD2 for converting light of the blue color into light of the green color and the light scattering particles. For example, the third light conversion pattern CCP3 may include the light scattering particles SCT. For example, the light scattering particles SCT may scatter light of the blue color.

Accordingly, lights of different colors may be emitted from the first to third conversion patterns CCP1 to CCP3. For example, light of a color obtained by mixing the red color and the blue color may be emitted from the first light conversion pattern CCP1. For example, light of a color obtained by mixing the green color and the blue color may be emitted from the second light conversion pattern CCP2. For example, light of the blue color may be emitted from the third light conversion pattern CCP3. Lights of different colors, which are emitted from the first to third light conversion patterns CCP1 to CCP3, may be emitted light of the red color, light of the green color, and light of the blue color while passing through the first to third color filters CF1 to CF3 of the color filter layer CFL, respectively. Therefore, the first to third sub-pixels SP1 to SP3 may be provided as a red sub-pixel, a green sub-pixel, and a blue sub-pixel, respectively.

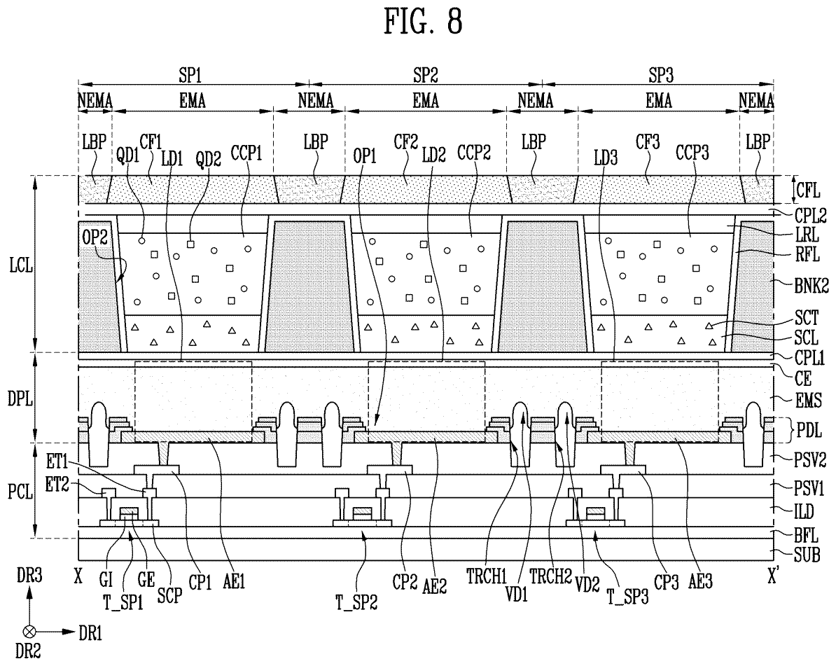

FIG. 8 is a schematic cross-sectional view of a pixel taken along the line X-X′ shown in FIG. 5 in accordance with an embodiment of the disclosure. In relation to FIG. 8, descriptions of portions overlapping with those shown in FIG. 6 will be simplified or omitted.

Referring to FIG. 8, the display panel layer DPL may include first to third anodes AE1 to AE3, a pixel defining layer PDL, a light emitting structure EMS, a cathode CE, and a first capping layer CPL1. Each of first to third light emitting elements LD1 to LD3 shown in FIG. 8 may be configured as an organic light emitting diode.

The pixel defining layer PDL may include first openings OPI exposing portions of the first to third anodes AE1 to AE3 in a plan view. The pixel defining layer PDL may include multiple inorganic insulating layers. Each of the inorganic insulating layers may include at least one of silicon oxide (SiOₓ) and silicon nitride (SiNₓ). For example, the pixel defining layer PDL may include first to third inorganic insulating layers which are sequentially stacked, and each of the first to third inorganic insulating layers may include at least one of silicon nitride, silicon oxide, and silicon oxynitride. However, embodiments are not limited thereto. The first to third inorganic insulating layers may have a step-shaped section in an area adjacent to the first openings OP1.

A separator may be provided in a boundary area between sub-pixels adjacent to each other. The separator may cause a discontinuity to be formed in the light emitting structure EMS in the boundary area. For example, the light emitting structure EMS may be cut or bent by the separator in the boundary area.

The separator may be provided in or on the pixel defining layer PDL. The pixel defining layer PDL may include one or more trenches TRCH1 and TRCH2 as a separator.

In an embodiment, the one or more trenches TRCH1 and TRCH2 may penetrate the pixel defining layer PDL, and partially penetrate the second passivation layer PSV2. In an embodiment, the one or more trenches TRCH1 and TRCH2 may penetrate the pixel defining layer PDL and the second passivation layer PSV2, and partially penetrate the first passivation layer PSV1. In an embodiment, the one or more trenches TRCH1 and TRCH2 may at least partially penetrate the second passivation layer PSV2 and/or the first passivation layer PSV1, and a portion of the pixel defining layer PDL may be disposed in the one or more trenches TRCH1 and TRCH2.

The pixel defining layer PDL may include two trenches TRCH1 and TRCH2 in the boundary area. However, embodiments are not limited thereto. For example, the pixel defining layer PDL may include one trench in the boundary area. In another embodiment, the pixel defining layer PDL may include three or more trenches in the boundary area.

Due to first and second trenches TRCH1 and TRCH2, discontinuities such as a first void VD1 and a second void VD2 may be formed in the light emitting structure EMS in the boundary area. Some of multiple layers stacked in the light emitting structure EMS may be cut or bent by the first and second voids VD1 and VD2. For example, at least one charge generation layer included in the light emitting structure EMS may be cut by the first and second voids VD1 and VD2. As such, due to the first and second trenches TRCH1 and TRCH2, portions of the light emitting structure EMS, included in the first to third sub-pixels SP1 to SP3, may be at least partially separated from each other.

In FIG. 8, it is illustrated that the first and second voids VD1 and VD2 are formed in the light emitting structure EMS in the boundary area. However, embodiments are not limited thereto. For example, a concave-shaped valley may be formed in the light emitting structure EMS in the boundary area. The discontinuities formed in the light emitting structure EMS may be variously changed according to shapes of the first and second trenches TRCH1 and TRCH2.

The light emitting structure EMS may be disposed on the first to third anodes AE1 to AE3 exposed by the first openings OP1 of the pixel defining layer PDL. In embodiments, the light emitting structure EMS may be formed through a process such as vacuum deposition or inkjet printing. The light emitting structure EMS may fill the first openings OP1 of the pixel defining layer PDL, and be entirely disposed throughout the first to third sub-pixels SP1 to SP3. As described above, the light emitting structure EMS may be partially cut or bent by the separator in the boundary area. Accordingly, in an operation of the display device DP (see FIG. 3), the magnitude of current leaked from each of the first to third sub-pixels SP1 to SP3 to an adjacent sub-pixel through the layers included in the light emitting structure EMS may be decreased. Thus, first to third light emitting elements LD1 to LD3 may operate with a relatively high reliability.

The cathode CE may be disposed over the light emitting structure EMS. The cathode CE may be commonly provided in the first to third sub-pixels SP1 to SP3. The cathode CE may serve as a half mirror which allow light emitted from the light emitting structure EMS to be partially transmitted therethrough and to be partially reflected therefrom.

The first anode AE1, a portion of the light emitting structure EMS, which overlaps the first anode AE1, and a portion of the cathode CE, which overlaps the first anode AE1, may constitute the first light emitting element LD1. The second anode AE2, a portion of the light emitting structure EMS, which overlaps the second anode AE2, and a portion of the cathode CE, which overlaps the second anode AE2, may constitute the second light emitting element LD2. The third anode AE3, a portion of the light emitting structure EMS, which overlaps the third anode AE3, and a portion of the cathode CE, which overlaps the third anode AE3, may constitute the third light emitting element LD3.

The first capping layer CPL1 may be disposed over the cathode CE. The first capping layer CPL1 may serve as an encapsulation layer which prevents oxygen and/or moisture from infiltrating into the display panel layer DPL.

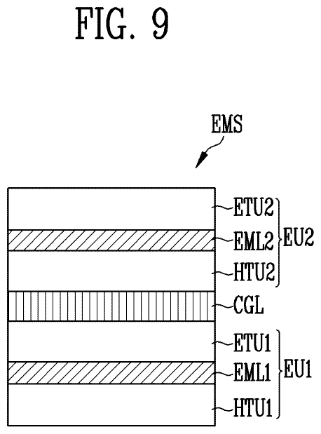

FIG. 9 is a schematic cross-sectional view of a light emitting structure included in one of the first to third light emitting elements shown in FIG. 8 in accordance with an embodiment of the disclosure.

Referring to FIG. 9, the light emitting structure EMS may have a tandem structure in which first and second light emitting units EU1 and EU2 are stacked. The light emitting structure EMS may be configured substantially identically in each of the first to third light emitting elements LD1 to LD3 shown in FIG. 8.

Each of the first and second light emitting units EU1 and EU2 may include at least one light emitting layer generating light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2. In an embodiment, the second light emitting layer EML2 may be an organic light emitting layer including an organic material.

Each of the first and second hole transport units HTU1 and HTU2 may include at least one of a hole injection layer and a hole transport layer. In an embodiment, each of the first and second hole transport units HTU1 and HTU2 may further include a hole buffer layer, an electron blocking layer, and the like. The first and second hole transport units HTU1 and HTU2 may have a same configuration or have different configurations.

Each of the first and second electron transport units ETU1 and ETU2 may include at least one of an electron injection layer and an electron transport layer. In an embodiment, each of the first and second electron transport units ETU1 and ETU2 may further include an electron buffer layer, a hole blocking layer, and the like. The first and second electron transport units ETU1 and ETU2 may have a same configuration or have different configurations.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. In embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or a combination thereof. However, embodiments are not limited thereto.

In embodiments, the first light emitting layer EML1 and the second light emitting layer EML2 may generate light of a same color. For example, the first light emitting layer EML1 and the second light emitting layer EML2 may generate light of a blue color. However, embodiments are not limited thereto. For example, one of the first light emitting layer EML1 and the second light emitting layer EML2 may generate light of the blue color, and another one of the first light emitting layer EML1 and the second light emitting layer EML2 may generate light of a color different from the blue color.

Unlike as shown in FIG. 9, in another embodiment, the light emitting structure EMS may include one light emitting unit in each of the first to third light emitting elements LD1 to LD3. The light emitting unit included in each of the first to third light emitting elements LD1 to LD3 may be configured to emit light of a same color. For example, the light emitting units of the first to third light emitting elements LD1 to LD3 may emit light of the blue color. Light emitting units of the first to third sub-pixels SP1 to SP3 may be separated from each other, and the separated light emitting units may be disposed in the first openings OP1 of the pixel defining layer PDL.

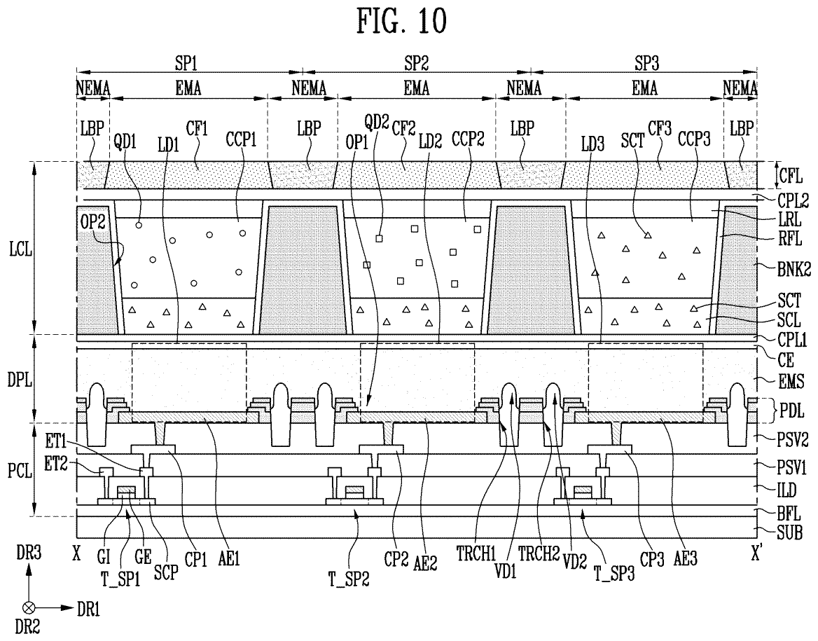

FIG. 10 is a schematic cross-sectional view of a pixel taken along the line X-X′ shown in FIG. 5 in accordance with an embodiment of the disclosure. In relation to FIG. 10, descriptions of portions overlapping with those shown in FIG. 6 will be simplified or omitted.

Referring to FIG. 10, the first to third light emitting elements LD1 to LD3 may emit light of the blue color. In an embodiment, the first to third light conversion patterns CCP1 to CCP3 may be configured with different materials. For example, the first light conversion pattern CCP1 may include the first color conversion particles QD1 for converting light of the blue color into light of the red color and the light scattering particles. For example, the second light conversion pattern CCP2 may include the second color conversion particles QD2 for converting light of the blue color into light of the green color and the light scattering particles. For example, the third light conversion pattern CCP3 may include the light scattering particles SCT. For example, the light scattering particles SCT may scatter light of the blue color.

Accordingly, lights of different colors may be emitted from the first to third conversion patterns CCP1 to CCP3. For example, light of a color obtained by mixing the red color and the blue color may be emitted from the first light conversion pattern CCP1. For example, light of a color obtained by mixing the green color and the blue color may be emitted from the second light conversion pattern CCP2. For example, light of the blue color may be emitted from the third light conversion pattern CCP3. Lights of different colors, which are emitted from the first to third light conversion patterns CCP1 to CCP3, may be emitted as light of the red color, light of the green color, and light of the blue color while passing through the first to third color filters CF1 to CF3 of the color filter layer CFL, respectively. Therefore, the first to third sub-pixels SP1 to SP3 may be provided as a red sub-pixel, a green sub-pixel, and a blue sub-pixel, respectively.

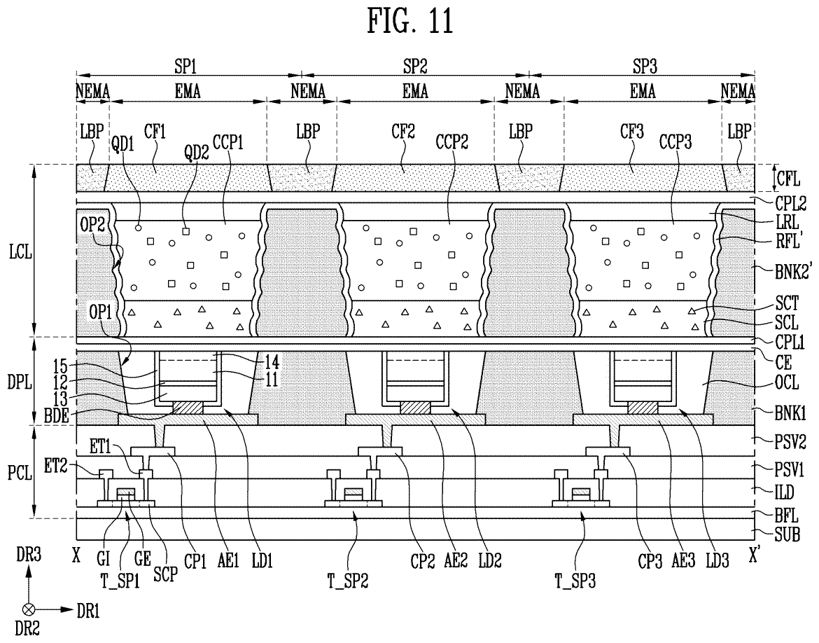

FIG. 11 is a schematic cross-sectional view of a pixel taken along the line X-X′ shown in FIG. 5 in accordance with an embodiment of the disclosure. In relation to FIG. 11, descriptions of portions overlapping with those shown in FIG. 6 will be simplified or omitted.

Referring to FIG. 11, a surface of a second bank BNK2′ may have an uneven structure. For example, a side surface of the second bank BNK2′ may have an uneven structure. The uneven structure may be formed in various shapes such as a triangular pyramid, a quadrangular pyramid, a trapezoid, and a hemisphere in a cross-sectional view. Like the second bank BNK2′, a reflective layer RFL′ disposed on the side surface of the second bank BNK2′ may have an uneven structure. The uneven structure may induce diffuse reflection and recycling of light of the blue color, which is emitted from the first to third light emitting elements LD1 to LD3. Accordingly, emission (or leakage) of light of the blue color in the first and second light conversion patterns CCP1 and CCP2 may be reduced, and the light conversion efficiency of the first color conversion particles QD1 and the second color conversion particles QD2 may be improved.

The uneven structure of the second bank BNK2′ and the reflective layer RFL′, shown in FIG. 11, may be applied to the embodiments shown in FIGS. 7, 8, 10, 11, and 12.

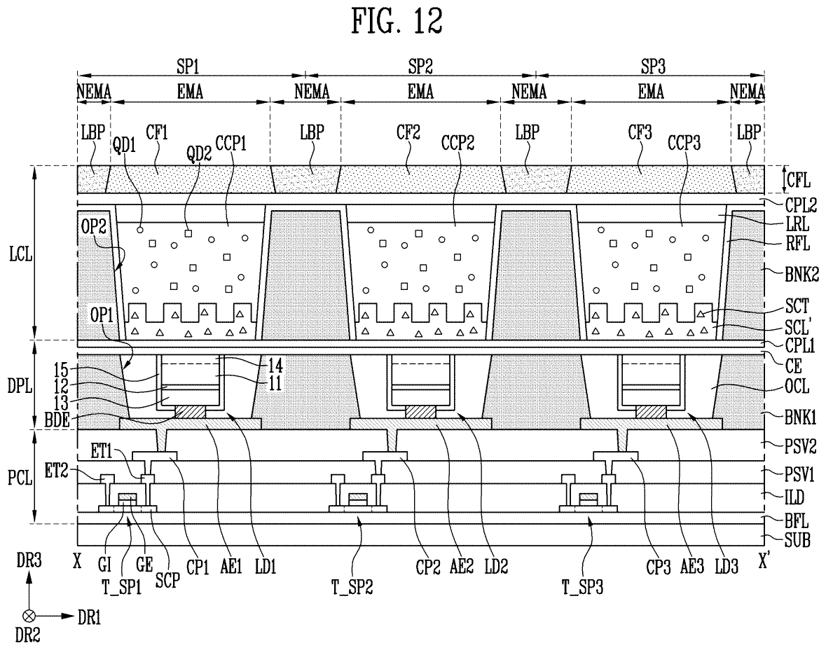

FIG. 12 is a schematic cross-sectional view of a pixel taken along the line X-X′ shown in FIG. 5 in accordance with an embodiment of the disclosure. In relation to FIG. 12, descriptions of portions overlapping with those shown in FIG. 6 will be simplified or omitted.

Referring to FIG. 12, a light scattering layer SCL′ may have a fine pattern configured with the light scattering particles SCT. For example, the fine pattern may be formed in various shapes such as a cylinder, a hemisphere, a pyramid, and a quadrangular pillar in a cross-sectional view. The fine pattern may have a size appropriate for light of the blue color, which is emitted from the first to third light emitting elements LD1 to LD3, to be output in the Lambertian form. For example, the size of the fine pattern may be greater than about ¼ of the wavelength of the light of the blue color, which is emitted from the first to third light emitting elements LD1 to LD3, and be smaller than the wavelength of the light of the blue color, which is emitted from the first to third light emitting elements LD1 to LD3. The number of fine patterns formed in the light scattering layer SCL′ is not particularly limited.

The light scattering layer SCL′ having the fine pattern may be formed through a nanoimprint process. For example, the light scattering particles SCT may be coated on the first capping layer CPL1 in the second openings OP2, and be stamped using a mold having a shape corresponding to the fine pattern. The mold may include an ultraviolet curable resin such as polydimethylsiloxane (PDMS). Subsequently, after ultraviolet light is irradiated, the mold may be removed, thereby forming the light scattering layer SCL′ having the fine pattern. However, embodiments are not limited thereto.

The light scattering layer SCL′ having the fine pattern shown in FIG. 12 may be applied to the embodiments shown in FIGS. 7, 8, 10, and 11.

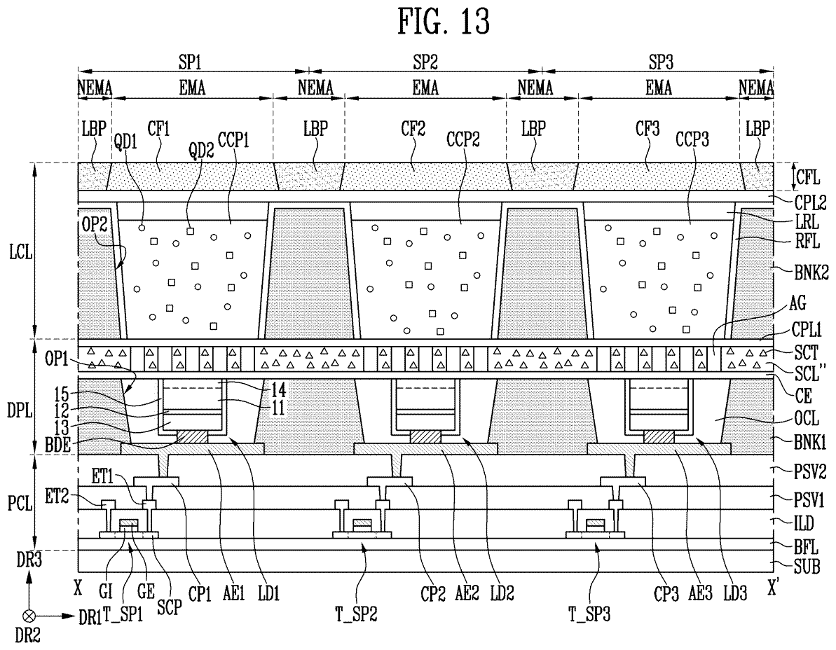

FIG. 13 is a schematic cross-sectional view of a pixel taken along the line X-X′ shown in FIG. 5 in accordance with an embodiment of the disclosure. In relation to FIG. 13, descriptions of portions overlapping with those shown in FIG. 6 will be simplified or omitted.

Referring to FIG. 13, a light scattering layer SCL″ may be disposed on the cathode CE. The light scattering layer SCL″ may have a lattice structure including air gaps AG. The lattice structure may include a base material including the light scattering particles SCT and the air gaps AG corresponding to openings filled with air. For example, the air gaps AG may be formed in various shapes such as a cylinder, a hemisphere, a pyramid, and a quadrangular pillar in a cross-sectional view. The air gaps AG may be formed at positions overlapping the first to third light conversion patterns CCP1 to CcP3 in a plan view. Each of the air gaps AG may have a size appropriate for light of the blue color to be output in the Lambertian form. For example, the size of the air gaps AG may be greater than about ¼ of the wavelength of the light of the blue color, which is emitted from the first to third light emitting elements LD1 to LD3, and be smaller than the wavelength of the light of the blue color, which is emitted from the first to third light emitting elements LD1 to LD3. The number of air gaps AG formed in the light scattering layer SCL″ having the lattice structure is not particularly limited. The light scattering layer SCL″ having the lattice structure may be formed through the above-described nanoimprint process, but embodiments of the disclosure are not limited thereto.

The light scattering layer SCL″ having the lattice structure, which is shown in FIG. 13, may be applied to the embodiments shown in FIGS. 7, 8, 10, and 11.

The first capping layer CPL1 may be disposed over the light scattering layer SCL″. The first capping layer CPL1 may prevent oxygen, moisture, and the like from infiltrating into the display panel layer DPL.

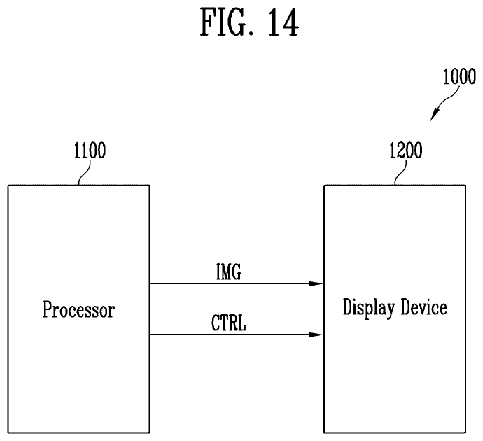

FIG. 14 is a schematic block diagram illustrating an embodiment of a display system.

Referring to FIG. 14, a display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be configured identical to the display device DD described with reference to FIG. 1. The image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

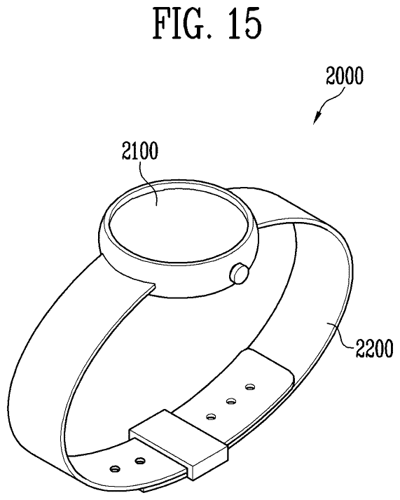

FIGS. 15 to 18 are perspective views illustrating application of the display system shown in FIG. 14 in accordance with an embodiment of the disclosure.

Referring to FIG. 15, the display system 1000 shown in FIG. 14 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100, so that image data including time information may be provided to the user.

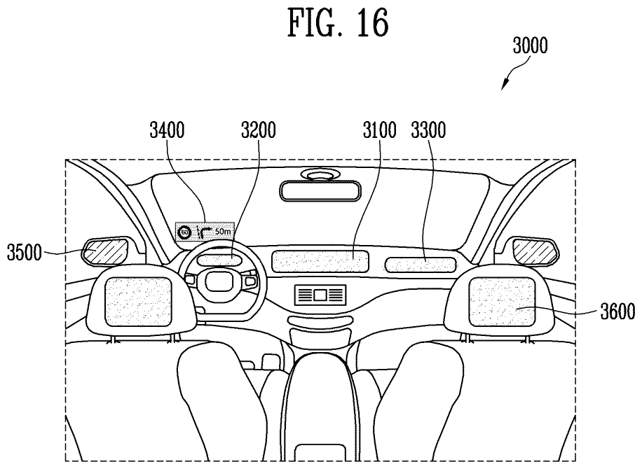

Referring to FIG. 16, the display system 1000 shown in FIG. 14 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a co-driver display 3300, a head-up display 3400, a side mirror display 3500, and a read seat display 3600, which are provided in the vehicle.

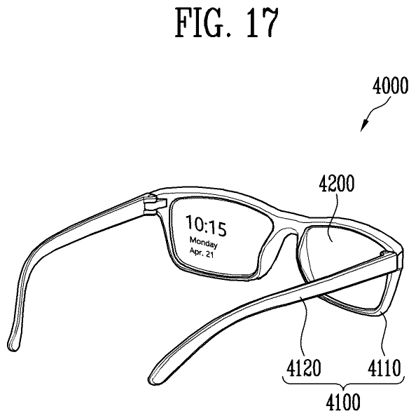

Referring to FIG. 17, the display system 1000 shown in FIG. 14 may be applied to smart glasses 4000. The smart glasses 4000 may be a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. In an embodiment, a projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, a transparent synthetic resin, and the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a display device. The display device 1200 may be applied to the projector and/or the lens part 4200.

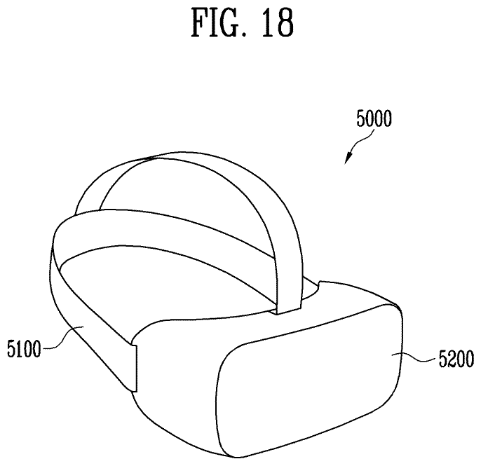

Referring to FIG. 18, the display system 1000 shown in FIG. 14 may be applied to a head mounted display device 5000.

The head mounted display device 5000 may be a wearable electronic device which may be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
a pixel circuit layer on a substrate;
light emitting elements on the pixel circuit layer, wherein the light emitting elements are included in a first sub-pixel, a second sub-pixel, and a third sub-pixel, respectively;
a light scattering layer on the light emitting elements;
a light conversion pattern on the light scattering layer, the light conversion pattern comprising color conversion particles; and
a color filter layer on the light conversion pattern.

2. The display device of claim 1, wherein the light emitting elements emit light of a blue color.

3. The display device of claim 2, wherein the light scattering layer comprises light scattering particles which scatter the light of the blue color.

4. The display device of claim 3, wherein the light scattering particles have a size in a range of about 100 nm to about 400 nm.

5. The display device of claim 1, wherein the color conversion particles comprise at least one of a quantum dot having a core-shell structure, a quantum rod having a core-shell structure, and a tetrapod quantum dot having a core-shell structure.

6. The display device of claim 1, wherein the color conversion particles comprise a nanophosphor.

7. The display device of claim 3, wherein the light conversion pattern comprises a first light conversion pattern, a second light conversion pattern, and a third light conversion pattern, each including first color conversion particles for converting the light of the blue color into light of a red color and second color conversion particles for converting the light of the blue color into light of a green color.

8. The display device of claim 7, wherein the color filter layer comprises:
a first color filter overlapping the first light conversion pattern in a plan view, the first color filter transmitting the light of the red color;
a second color filter overlapping the second light conversion pattern in a plan view, the second color filter transmitting the light of the green color; and
a third color filter overlapping the third light conversion pattern in a plan view, the third color filter transmitting the light of the blue color.

9. The display device of claim 7, wherein the color filter layer comprises:
a first color filter overlapping the first light conversion pattern in a plan view, the first color filter transmitting light of a yellow color;
a second color filter overlapping the second light conversion pattern in a plan view, the second color filter transmitting the light of the yellow color; and
a third color filter overlapping the third light conversion pattern in a plan view, the third color filter transmitting the light of the blue color.

10. The display device of claim 3, wherein the light conversion pattern comprises:
a first light conversion pattern comprising first color conversion particles converting the light of the blue color into light of a red color;
a second light conversion pattern comprising second color conversion particles converting the light of the blue color into light of a green color; and
a third light conversion pattern comprising the light scattering particles.

11. The display device of claim 10, wherein the color filter layer comprises:
a first color filter overlapping the first light conversion pattern in a plan view, the first color filter transmitting the light of the red color;
a second color filter overlapping the second light conversion pattern in a plan view, the second color filter transmitting the light of the green color; and
a third color filter overlapping the third light conversion pattern in a plan view, the third color filter transmitting the light of the blue color.

12. The display device of claim 2, wherein each of the light emitting elements comprises:
a first semiconductor layer including an n-type dopant;
an active layer disposed on the first semiconductor layer; and
a second semiconductor layer disposed on the active layer, the second semiconductor layer including a p-type dopant.

13. The display device of claim 2, wherein each of the light emitting elements comprises:
an anode;
a light emitting structure including at least one organic light emitting layer, the light emitting structure overlapping the anode in a plan view; and
a cathode on the light emitting structure, the cathode overlapping the anode in a plan view.

14. The display device of claim 1, further comprising:
a low refractive layer on the light conversion pattern.

15. The display device of claim 14, further comprising:
a bank partitioning the light scattering layer, the light conversion pattern, and the low refractive layer.

16. The display device of claim 15, wherein a surface of the bank has an uneven structure.

17. The display device of claim 15, further comprising:
a reflective layer on a top surface and a side surface of the bank.

18. The display device of claim 2, wherein the light scattering layer has a fine pattern.

19. The display device of claim 2, further comprising:
a capping layer disposed between the light scattering layer and the light conversion pattern.

20. The display device of claim 19, wherein the light scattering layer has a lattice structure including air gaps.
